(19) United States
(12) Patent Application Publication
(10) Pub. No.: US 2025/0293068 A1
(43) Pub. Date: Sep. 18, 2025

(54) WAFER PROCESSING DEVICE

(71) Applicant: SwaySure Technology Co., Ltd., Shenzhen (CN)

(72) Inventor: PENG ZHANG, Shenzhen (CN)

(21) Appl. No.: 18/980,171

(22) Filed: Dec. 13, 2024

(30) Foreign Application Priority Data
Mar. 14, 2024 (CN) 202410297570.5

(51) Int. Cl. H01L 21/677

(52) U.S. Cl. CPC H01L 21/67778; H01L 21/67745; H01L 21/67766; H01L 21/67772

(57) ABSTRACT

A wafer processing device includes a furnace tube, a loading and unloading region and an isolation door device, the loading and unloading region includes a wafer boat loading and unloading region and a wafer loading and unloading region connected via a communication region, the wafer boat loading and unloading region includes a first wafer boat loader for at least moving a wafer boat into or out of the furnace tube, and the wafer loading and unloading region includes a wafer loader for at least moving a wafer into or out of the wafer boat; the isolation door device is capable of isolating the wafer boat loading and unloading region from the wafer loading and unloading region, and operating to enable a transferring of the wafer between the wafer boat loading and unloading region and the wafer loading and unloading region through the communication region.

### CROSS-REFERENCE TO RELATED APPLICATIONS

This application claims priority to Chinese Patent Application No. 202410297570.5, filed on Mar. 14, 2024, the entire disclosure of which is hereby incorporated herein by reference.

### TECHNICAL FIELD

The present application belongs to the technical field of semiconductor manufacturing equipment, and specifically relates to a wafer processing device.

### BACKGROUND

The wafer processing device may include a furnace tube and a loading and unloading region connected to each other, and when the wafer on the first wafer boat in the loading and unloading region are moved into the furnace tube by the wafer boat elevator for heat treatment, the second wafer boat in the loading and unloading region may be loaded with wafers in the staging position to improve production efficiency.

When the wafer on the first wafer boat is processed completely, the wafer boat elevator moves the first wafer boat out of the furnace tube, the wafer boat transfer device places the first wafer boat in the staging position, and the wafer boat transfer device then transfers the second wafer boat to the wafer boat elevator, and the wafer boat elevator moves the second wafer boat into the furnace tube for heat treatment.

When the first wafer boat is moved into the furnace tube, because the air pressure in the furnace tube is higher than the loading and unloading region, the reaction by-products in the furnace tube will be sprayed out of the furnace tube, to contaminate the wafer on the second wafer boat. In addition, before the second wafers are moved from the staging region into the furnace tube and during the process of moving into the furnace tube, the reaction by-products on the first wafers will also spread to the second wafers, contaminating the wafer on the second wafers.

### SUMMARY

There is provided a wafer processing device according to embodiments of the present disclosure. The technical solution is as below.

According to a first aspect of embodiments of the present application, there is provided a wafer processing device, which includes:
a furnace tube;
a loading and unloading region, including a wafer boat loading and unloading region and a wafer loading and unloading region connected via a communication region, where the wafer boat loading and unloading region is in communication with the furnace tube, the wafer boat loading and unloading region comprises a first wafer boat loader for at least moving a wafer boat into or out of the furnace tube, and the wafer loading and unloading region comprises a wafer loader for at least moving a wafer into or out of the wafer boat; and
an isolation door device, provided in the communication region, where the isolation door device is capable of isolating the wafer boat loading and unloading region from the wafer loading and unloading region, and operating to enable a transferring of the wafer between the wafer boat loading and unloading region and the wafer loading and unloading region through the communication region.

Other features and advantages of the present application will become apparent by the following detailed description, or will be learned in part by practice of the present application.

It should be understood that the above general description and the detailed description that follows are exemplary and explanatory only and do not limit the present disclosure.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. Obviously, the accompanying drawings in the following description are only some of the embodiments of the present application, and other accompanying drawings may be obtained from these drawings without creative labor for those of ordinary skill in the art.

FIG. 1 is a front view of a wafer processing device in the first embodiment of the present application.

FIG. 2 is a top view of the wafer processing device in the first embodiment of the present application.

FIG. 3 is a view of by-product in the furnace tube spraying out to contaminate the wafer.

FIG. 4 is a view of diffusion of the by-product to contaminate the wafer.

FIG. 5 is a view of a contaminated wafer.

FIG. 6 is a view of a wafer boat holder holding a wafer boat in first embodiment of the present application.

FIG. 7 is a view of a wafer boat holder releasing a wafer boat in first embodiment of the present application.

FIG. 8 is a view of the support holder holding the wafer boat in first embodiment of the present application.

FIG. 9 is a view of closing of a first isolation door in first embodiment of the present application.

FIG. 10 is a view of an opening of the first isolation door in first embodiment of the present application.

FIG. 11 is a view of the first isolation door assembly forming a plurality of isolation partitions in first embodiment of the present application.

FIG. 12 is a view of a wafer processing device with a plurality of furnace tubes in first embodiment of the present application.

FIG. 13 is a view of a first cassette holder unit loading and unloading wafers in first embodiment of the present application.

FIG. 14 is a view of a second cassette holder unit loading and unloading wafers in first embodiment of the present application.

FIG. 15 is a front view of a wafer processing device in second embodiment of the present application.

FIG. 16 is a top view of the wafer processing device in second embodiment of the present application.

### DETAILED DESCRIPTION OF THE EMBODIMENTS

Example embodiments will now be described more fully with reference to the accompanying drawings. However, the example embodiments can be implemented in a variety of forms and should not be construed as being limited to the examples set forth herein; rather, the provision of these embodiments allows the present application to be more comprehensive and complete and conveys the idea of the example embodiments in a comprehensive manner to those skilled in the art.

In addition, the described features, structures, or characteristics may be combined in one or more embodiments in any suitable manner. In the following description, many specific details are provided thereby giving a full understanding of the embodiments of the present application. However, those skilled in the art will realize that it is possible to practice the technical embodiments of the present application without one or more of the specific details, or that other methods, components, devices, steps, and the like may be employed. In other cases, well-known methods, devices, implementations, or operations are not shown or described in detail to avoid blurring aspects of the present application.

The present application is described in further detail below in connection with the accompanying drawings and specific embodiments. It should be noted herein that the technical features involved in the various embodiments of the present application described below may be combined with each other as long as they do not constitute a conflict with each other. The embodiments described below by reference to the accompanying drawings are exemplary and are intended to be used for explaining the present application, and are not to be construed as a limitation of the present application.

### First Embodiment

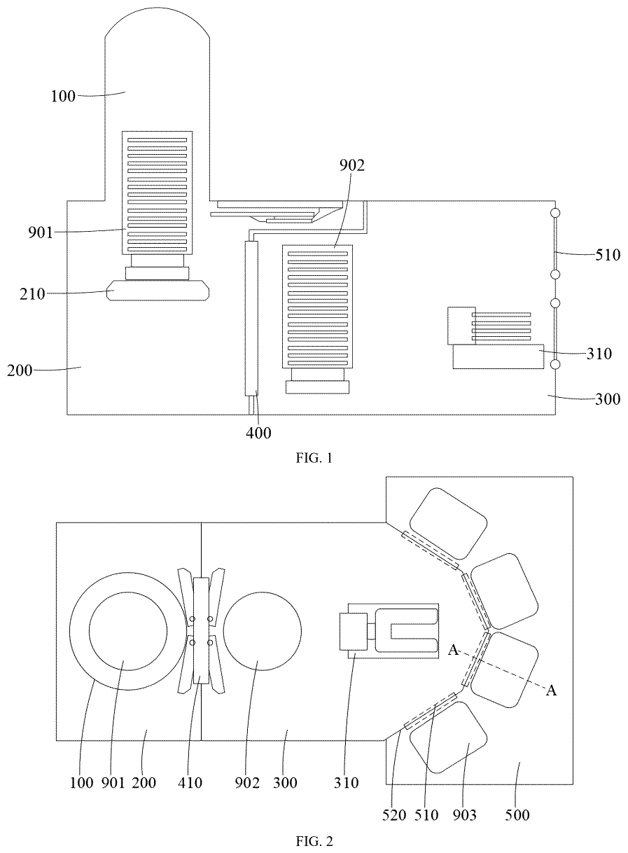

Referring to FIGS. 1 and 2, a wafer processing device in this embodiment includes: a furnace tube 100, a loading and unloading region, and an isolation door device. The loading and unloading region includes a wafer boat loading and unloading region 200 and a wafer loading and unloading region 300 connected via a communication region, and the wafer boat loading and unloading region 200 is in communication with the furnace tube 100. The wafer boat loading and unloading region 200 includes a first wafer boat loader 210 for at least moving a wafer boat into or out of the furnace tube 100. The wafer loading and unloading region 300 includes a wafer loader 310 for at least moving a wafer into or out of the wafer boat. The wafer loader 310 is configured to move the wafer into or out of the wafer cassette 903.

The isolation door device is provided in the communication region, and in a stationary state, the isolation door device is able to isolate the wafer boat loading and unloading region 200 and the wafer loading and unloading region 300, and the isolation door device is able to operate, so that the wafer boat can transfer between the wafer boat loading and unloading region 200 and the wafer loading and unloading region 300 through the communication region. That is to say, the isolation door device is opened only briefly when the wafer boat passes through, so that the wafer boat can transfer between the wafer boat loading and unloading region 200 and the wafer loading and unloading region 300 through the communication region, and the wafer boat loading and unloading region 200 and the wafer loading and unloading region 300 are isolated by the isolation door device when there is no the wafer boat passing through.

In the existing wafer processing device, when the wafer on the first wafer boat in the loading and unloading region are moved into the furnace tube for heat treatment by the wafer boat elevator, the second wafer boat in the loading and unloading region may be loaded with the wafer in the staging position in order to improve the production efficiency. When the wafer processing on the first wafer boat is completed, the wafer boat elevator moves the first wafer boat to the furnace tube, the wafer boat transfer device places the first wafer boat in the staging position, the wafer boat transfer device then transfers the second wafer boat to the wafer boat elevator, and the wafer boat elevator moves the second wafer boat into the furnace tube for heat treatment.

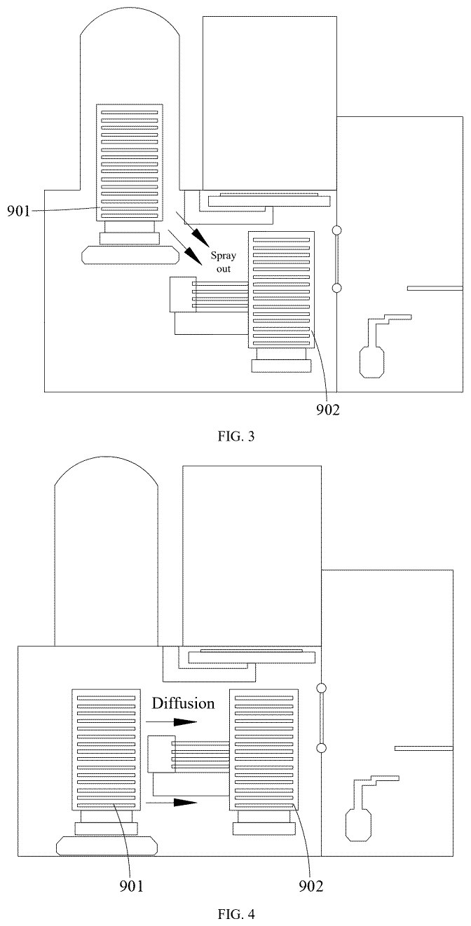

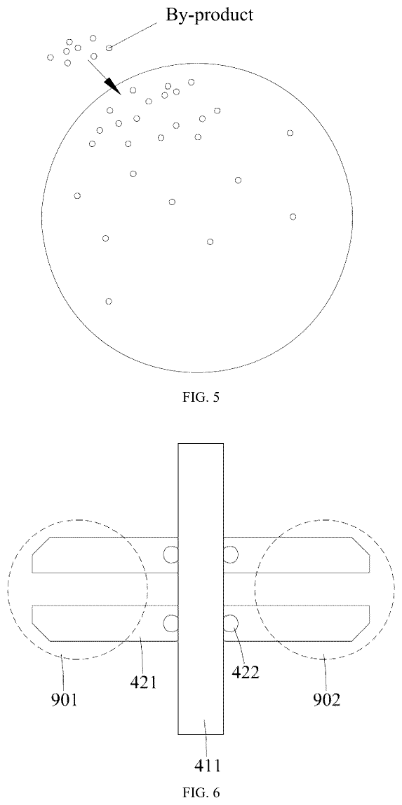

Referring to FIGS. 3 to 5, it is shown that when the first wafer boat 901 is moved into the furnace tube, since the air pressure in the furnace tube is higher than the loading and unloading region, the reaction by-products in the furnace tube will be sprayed out of the furnace tube, contaminating the wafer on the second wafer boat 902. Even if the air for blowing is provided in the loading and unloading region, the air for blowing cannot prevent the wafer on the second wafer boat 902 from being contaminated due to the fact that the by-products are ejected at a speed much greater than the speed of the air for blowing. In addition, before the second wafer boat 902 is moved from the staging region into the furnace tube and during the process of moving into the furnace tube, the reaction by-products on the first wafer boat 901 also spread to the second wafer boat 902, contaminating the wafer on the second wafer boat 902. Even if the air for blowing is provided in the loading and unloading region, the air for blowing can only blow to remove some of the diffused by-products, and cannot fundamentally solve the problem of the wafer being contaminated. The problem that contamination of a side of the wafer on the second wafer boat 902 near the furnace tube is contaminated, becomes more pronounced.

The wafer processing device in this embodiment includes: a furnace tube 100, a loading and unloading region and an isolation door device, the loading and unloading region includes a wafer boat loading and unloading region 200 and a wafer loading and unloading region 300 connected by a communication region, the wafer boat loading and unloading region 200 is in communication with the furnace tube 100. The wafer boat loading and unloading region 200 includes a first wafer boat loader 210, the first wafer boat loader 210 is configured to move the wafer boat in or out of the furnace tube 100 at least, the wafer loading and unloading region 300 includes a wafer loader 310, the wafer loader 310 is configured to move the wafer into or out of the wafer boat, the isolation door device is provided in the communication region, the isolation door device is capable of isolating the wafer boat loading and unloading region 200 from the wafer loading and unloading region 300, and the isolation door device is capable of operating, so that the wafer boat can transfer between the wafer boat loading and unloading region 200 and the wafer loading and unloading region 300 through the communication region. Since the isolation door device is only briefly opened when the wafer boat passes through, so that the wafer boat can transfer between the wafer boat loading and unloading region 200 and the wafer loading and unloading region 300 through the communication region, the wafer boat loading and unloading region 200 and the wafer loading and unloading region 300 are isolated by the isolation door device when there is no wafer boat passing through, which blocks by-products generated from the reaction in the furnace tube 100 from passing through the communication region, thereby reducing the risk of by-product contaminating the wafer boat and the wafer on the wafer boat, and improving the yield of the product.

It is to be noted that when the wafer boat is moved to the furnace tube 100, the wafer boat loading and unloading region 200 and the wafer loading and unloading region 300 are isolated by the isolation door device, and the air for blowing can be set up in the wafer boat loading and unloading region 200 and the wafer loading and unloading region 300, when the by-products of the reaction on the wafer boat in the wafer boat loading and unloading region 200 and the wafer loading and unloading region 300 are blown away to meet the requirements, the isolation door device operates, that is, the wafer boat loading and unloading region 200 and the wafer loading and unloading region 300 are communicated briefly. The wafer boat is able to flow between the wafer boat loading and unloading region 200 and the wafer loading and unloading region 300, which further reduces the risk of the by-product contaminating the wafer boat and the wafer on the wafer boat, and improves the yield of the product.

In some embodiments, the isolation door device can drive the wafer boat to move, so that the wafer boat can transfer between the wafer loading and unloading region 200 and the wafer loading and unloading region 300 through the communication region. That is, the wafer loading and unloading region 200 is isolated from the wafer loading and unloading region 300 when the isolation door device is in the stationary state. When the isolation door device operates, the first wafer boat 901 in the wafer loading and unloading region 200 is driven to move to the wafer loading and unloading region 300, and the second wafer boat 902 in the wafer loading and unloading region 300 is driven to move to the wafer loading and unloading region 200. After the second wafer boat 902 is fed into the furnace tube 100 for processing and the first wafer boat 901 is unloaded in the wafer loading and unloading region 300, and the wafer is reloaded in the wafer loading and unloading region 300, the isolation door device may again exchange the regions where the two wafer boats are located, so that the two wafer boats circulate between the wafer boat loading and unloading region 200 and the wafer loading and unloading region 300, continuously feeding unprocessed wafers from the wafer loading and unloading region 300 to the furnace tube 100 for processing, and after the wafer is processed and sent back to the wafer loading and unloading region 300 and transferred to the next process.

The isolation door device both isolates the wafer boat loading and unloading region 200 and the wafer loading and unloading region 300, and exchanges the regions where the two wafer boats are located while the isolation door device is started, shortening the time for the wafer boat loading and unloading region 200 and the wafer loading and unloading region 300 to be communicated, and helping to minimize the risk of contamination of the wafer boat and the wafer on the wafer boat by by-products.

Exemplarily, the isolation door device includes a first isolation door assembly 400, the first isolation door assembly 400 includes a first isolation door 410 and a plurality of wafer boat transfer mechanisms. Each wafer boat transfer mechanism is configured to carry and move at least one wafer boat, and the plurality of wafer boat transfer mechanisms include a first wafer boat transfer mechanism and a second wafer boat transfer mechanism, the first wafer boat transfer mechanism and the second wafer boat transfer mechanism are provided on a first side and a second side the first isolation door 410 that opposite to each other.

At least the wafer boat transfer mechanism can rotate around the center of rotation, that is, the first isolation door 410 can be lifted or slid, so that the wafer boat loading and unloading region 200 and the wafer loading and unloading region 300 are communicated, and only the rotation of the wafer boat transfer mechanism realizes the exchange of the regions where the two wafer boats are located, and the wafer boat transfer mechanism can also be connected to the first isolation door 410, and the connection may be a direct or an indirect connection, and the connection may be a movable connection or a fixed connection, so that the wafer boat transfer mechanism and the first isolation door 410 rotate synchronously to realize the exchange of the regions where the two wafer boats are located. In some embodiments, the two wafer boat transfer mechanisms are arranged symmetrically at the center, and a common center point, i.e., the center of symmetry, between the two wafer boat transfer mechanisms may serve as the center of rotation of the wafer boat transfer mechanism. In other embodiments, the center of rotation is provided according to the actual situation.

The first wafer boat transfer mechanism and the second wafer boat transfer mechanism are distributed and provided on the first side and the second side the first isolation door 410 that are opposite to each other, and the wafer boat transfer mechanism is rotated 180° around the center of rotation to realize the exchange of the regions where the two wafer boats are located.

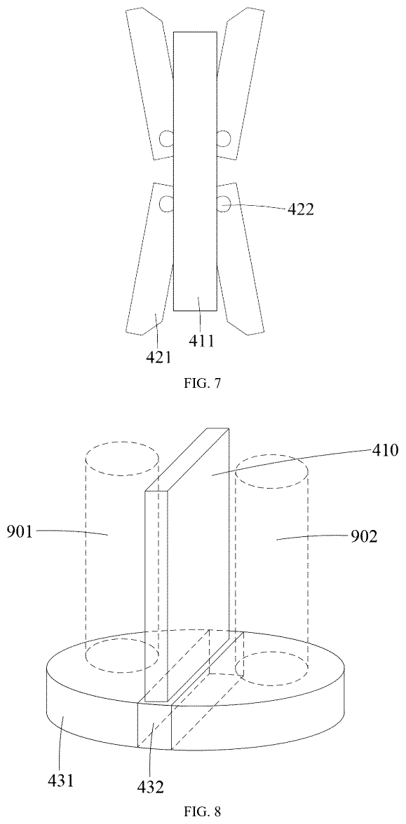

Referring to FIGS. 6 and 7, the wafer boat transfer mechanism includes a wafer boat holder and a holder rotation shaft, and the wafer boat holder is rotatably provided on the first isolation door 410 via the holder rotation shaft. The holder rotation shaft may be directly or indirectly connected to the first isolation door 410, and the connection may be a movable connection or a fixed connection, as long as the holder rotation shaft can be used as a rotation shaft of the wafer boat holder and can realize the synchronous rotation of the wafer boat transfer mechanism and the first isolation door 410. The wafer boat holder can rotate around the holder rotation shaft to hold the wafer boat to carry the wafer boat, the wafer boat holder can rotate around the holder rotation shaft to release the held wafer boat, and the wafer boat holder, the holder rotation shaft, and the first isolation door 410 can synchronously rotate around the center of rotation to move the held wafer boat, and to enable the plurality of wafer boat transfer mechanisms to be switched between the first state and the second state.

It is to be noted that the wafer boat transfer mechanism includes a wafer boat holder and a holder rotation shaft, and the wafer boat holder can rotate around the holder rotation shaft to hold or release the wafer boat, but is not limited to this, and the wafer boat transfer mechanism can also adopt a telescopic structure, and the wafer boat transfer mechanism holds or releases the wafer boat through the telescopic movement, which is dependent on the specific situation.

The wafer boat transfer mechanism includes a wafer boat holder and a holder rotation shaft, compared with the solution that the wafer boat transfer mechanism holds or releases the wafer boat through the telescopic, the wafer boat holder rotates around the holder rotation shaft to hold or release the wafer boat, which realizes the holding or releasing of the wafer boat in a simpler structure, the fabrication cost of the wafer processing device can be reduced and the robustness of the wafer boat transfer mechanism can be improved.

The wafer boat transfer mechanism includes a wafer boat holder and a holder rotation shaft, and the wafer boat holder rotates around the holder rotation shaft to hold or release the wafer boat.

In some embodiments, the wafer boat holder is a single arm holder, i.e., the wafer boat transfer mechanism holds or releases the wafer boat by the rotation of the wafer boat holder. Preferably, when the wafer boat holder is a single arm holder, there is a mating structure between the wafer boat holder and the wafer boat to enable the wafer boat holder to hold the wafer boat securely. The mating structure is, for example, a hooking mechanism or a holding mechanism, and the holding or releasing of the wafer boat is realized by the hooking mechanism or the holding mechanism.

In some embodiments, the wafer boat holder is a multi-armed clamping holder, i.e., the wafer boat holder includes a plurality of wafer boat sub-holders 421, and the wafer boat carrying mechanism holds or releases the wafer boat by the plurality of wafer boat sub-holders 421 being close to each other or away from each other, which is structurally simple and easy to operate.

Specifically, the wafer boat holder includes a plurality of wafer boat sub-holders 421, the holder rotation shaft includes a plurality of holder sub-shafts 422, the holder sub-shaft 422 is connected to the first isolation door 410, the connection can be directly or indirectly connected, and can be movably connected or fixedly connected, as long as the holder sub-shaft 422 can serve as a rotation shaft of the wafer boat sub-holders 421 and can realize synchronous rotation of the wafer boat carrying mechanism and the first isolation door 410, and each wafer boat carrying mechanism holds or releases the wafer boat by the plurality of wafer boat sub-holders 421. Each wafer boat holder 421 is rotatably connected to the first isolation door 410 through each holder sub-shaft 422, and the wafer boat holder 421 can rotate around the holder sub-shaft 422. As in the embodiment shown in FIGS. 6 and 7, the wafer boat holder includes two wafer boat sub-holders 421 and the holder rotation shaft includes two rotation sub-shafts 422, the rotation sub-shafts 422 are fixedly provided at least horizontally on the first isolation door 410. The wafer boat holder capable of rotating about the holder rotation shaft to hold the wafer boat to carry the wafer boat includes the plurality of wafer boat sub-holders 421 of the wafer boat holder capable of rotating to gather and clamp the wafer boat to carry the wafer boat. The wafer boat holder capable of rotating about the holder rotation shaft to release the held wafer boat includes the plurality of wafer boat sub-holders 421 of the wafer boat holder capable of rotating to separate to release the clamped wafer boat.

Preferably, the wafer boat holder includes two wafer boat sub-holders 421, and the holder rotation shafts include two holder sub-shafts 422, as shown in FIG. 6, which has a simple structural design, is easy to operate and can hold the wafer boat in a more stable manner. A wafer boat holder may be provided on each side of the first isolation door 410 to hold or release the wafer boat. In other embodiments, two or more wafer boat holders may be provided on the same side of the first isolation door 410, and a plurality of wafer boat holders may be spaced apart in the vertical direction to hold the wafer boat at the plurality of points to improve the stability of holding the wafer boat.

In some embodiments, the wafer boat transfer mechanism is configured to make at least the wafer boat holder capable of reciprocating along the vertical direction. Before the wafer boat holder, the holder rotation shaft, and the first isolation door 410 rotate about the center of rotation to move the held wafer boat, the wafer boat holder is able to rotate about the holder rotation shaft to hold the wafer boat to carry the wafer boat, and the wafer boat holder is able to rise to lift the held wafer boat. After the wafer boat holder, the holder rotation shaft, and the first isolation door 410 rotate about the center of rotation to move the held wafer boat, the wafer boat holder is able to descend to put down the held wafer boat and the wafer boat holder is capable of rotating about the holder rotation shaft to release the held wafer boat. For example, after the first wafer boat loader 210 removes the first wafer boat 901 from the furnace tube 100, the wafer boat holder is able to rotate about the holder rotation shaft to hold the wafer boat to carry the wafer boat, and then the wafer boat holder can rise to lift the carried wafer boat from the first wafer boat loader 210 to allow the wafer boat holder to rotate about the center of rotation for switching between the first and second states for exchanging the regions where the first wafer boat 901 and the second wafer boat 902 are located. Before the first wafer boat loader 210 moves the second wafer boat 902 into the furnace tube 100, the wafer boat holder is able to descend to place the second wafer boat 902 on the first wafer boat loader 210, and then the wafer boat holder is able to rotate about the holder rotation shaft to release the held wafer boat.

In some embodiments, the wafer boat holder is driven by the holder rotation shaft to achieve the reciprocation motion in the vertical direction, and the holder rotation shaft can reciprocate in the vertical direction, that is, movably connected to the first isolation door 410. In some embodiments, the holder rotation shaft is fixedly connected directly to the first isolation door 410, and the wafer boat holder is driven by the holder rotation shaft and the first isolation door 410 to achieve the reciprocation motion in the vertical direction.

The wafer boat holder can reciprocate along the vertical direction, the wafer boat can be lifted from the first wafer boat loader 210 when taking the wafer boat, and when releasing the wafer boat, the wafer boat can be rotated into place and then descended to release the wafer boat, so as to avoid collision of the wafer boat when being transferred, which affects the yield rate of the product. In addition, the wafer boat holder is capable of reciprocation motion in a vertical direction and holding or releasing the wafer boat, realizing a smooth handover of the wafer boat with the first wafer boat loader 210, and the wafer boat loading and unloading region 200 may not have to be provided with a wafer boat transfer device 800 for transferring the wafer boat to the wafer boat transfer mechanism from the first wafer boat loader 210, which reduces the fabrication cost of the wafer processing device.

Referring to FIG. 8, in some embodiments, the wafer boat transfer mechanism includes a support seat 431, two support seats 431 are provided on the first side and the second side of the first isolation door 410, and the support seat 431 is configured to carry the wafer boat and to move the carried wafer boat when rotating around the center of rotation. In the embodiment shown in FIG. 8, the two support seats 431 are symmetrically provided, and the center of rotation may be a common center point of the two support seats 431. In other embodiments, the center of rotation of the support seats 431 is set according to the actual need. When the wafer boat transfer mechanism includes the support seats 431, the wafer loading and unloading region 200 may be provided with the wafer boat transfer device 800 for transferring the wafer boat from the first wafer boat loader 210 to the support seats 431 or the wafer boat from the support seats 431 to the first wafer boat loader 210. In addition, a structure such as a suction cup or a snapping-slot may be provided on the support seat 431 for fixing the wafer boat to avoid tilting or shifting of the wafer boat when the support seat 431 is rotated around the center of rotation.

The wafer boat transfer mechanism includes the support seat 431, and the support seat 431 is utilized to carry and move the wafer boat, making the regions where the two wafer boats are located exchange easier.

In some embodiments, the support seat 431 of the first wafer boat transfer mechanism and the support seat 431 of the second wafer boat transfer mechanism are connected by a connection member 432, which is connected to the first isolation door 410, and the connection member 432 and the support seat 431 are provided on the same side of the first isolation door 410. The connection member 432 and the support seat 431 may be integrally connected, and a rotation driving device such as a motor may be provided on the sides of the connection member 432 and the support seat 431 away from the first isolation door 410. The support seat 431, the connection member 432, and the first isolation door 410 can rotate synchronously, so that the regions where the first wafer boat transfer mechanism and the second wafer boat transfer mechanism are located are exchanged, to realize exchanging of the regions where the two wafer boats are located.

The support seat 431 serves both as the wafer boat transfer mechanism for driving the wafer boat to rotate and as a base for driving the first isolation door 410 to rotate, simplifying the structure of the first isolation door assembly 400.

It is noted that the wafer boat transfer mechanism includes the support seat 431, or the wafer boat transfer mechanism includes the wafer boat holder and the holder rotation shaft, which is not limited herein. The wafer boat transfer mechanism may also include the support seat 431, the wafer boat holder, and the holder rotation shaft at the same time, which is determined as specific situation. The wafer boat transfer mechanism simultaneously includes the support seat 431, the wafer boat holder and the holder rotation shaft, the wafer boat holder and the wafer boat held by the holder rotation shaft are placed on the support seat 431, and the wafer boat is less likely to be tilted or shaken during rotation of the wafer boat transfer mechanism and the first isolation door 410, and the support seat 431 is taken as a support, the number of wafer boat sub-holders 421 of the wafer boat holder can be reduced, exemplarily to two.

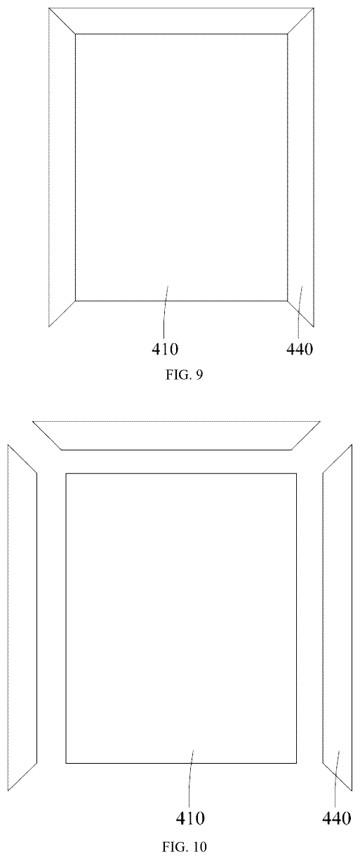

Referring to FIGS. 9 and 10, it is shown that the first isolation door 410 and the wafer boat transfer mechanism can rotate synchronously. The first isolation door assembly 400 also includes a sealing member 440, and the sealing member 440 can be provided between the first isolation door 410 and an inner wall of the loading and unloading region. Before the first isolation door 410 and the wafer boat transfer mechanism rotate, the sealing member 440 moves in a direction away from the first isolation door 410, so that a gap is formed between the first isolation door 410 and the first isolation door 410 when the first isolation door 410 and the wafer boat transfer mechanism rotate. When the first isolation door 410 and the wafer boat transfer mechanism stop rotating, the sealing member 440 moves in a direction proximate the first isolation door 410 to seal the gap between the loading region and the first isolation door 410.

The sealing member 440 is provided between the first isolation door 410 and the loading and unloading region, which can enhance the insolation effect of the first isolation door 410 and further reduces the risk of contamination of the wafer boat and the wafer on the wafer boat by by-products.

Referring to FIG. 11, the first isolation door 410 is a multi-winged revolving door, the multi-winged revolving door include at least three door wings 411, the at least three door wings 411 include two main door wings and at least one sub-door wing, the two main door wings are connected to divide a first side and a second side of the first isolation door 410, and the at least one sub-door wing is provided on the first side of the first isolation door 410 and/or the second side of the first isolation door 410. All of the door wings 411 are provided in a circular array and have a common shaft of rotation, i.e., a center of rotation. Each pair of adjacent door wings 411 forms an equal angle is formed between each pair of adjacent door wings 411, and an isolation partition is formed between the adjacent door wings 411, the angle between the door wings 411 corresponding to each isolation partition is the same.

The first isolation door assembly 400 includes a plurality of wafer boat transfer mechanisms, the plurality of wafer boat transfer mechanisms include a first wafer boat transfer mechanism, a second wafer boat transfer mechanism, . . . a pth wafer boat transfer mechanism, p is a number of isolation partitions. The wafer boat transfer mechanism is provided one-to-one between adjacent door wings 411, i.e., the wafer boat transfer mechanism is provided one-to-one in the isolation partition. The wafer boat transfer mechanism is capable of rotating around a center of rotation to drive the wafer boat to transfer between the wafer boat loading and unloading region 200 and the wafer loading and unloading region 300 through the communication region.

Each wafer boat transfer mechanism is capable of carrying and moving at least one wafer boat, the first isolation door 410 is a multi-winged revolving door, the door wings 411 of the multi-winged revolving door are provided in a circular array to form a plurality of isolation partitions, and the wafer boat transfer mechanisms are provided one by one correspondingly between adjacent door wings 411, and the wafer boat transfer mechanism and the first isolation door 410 in the first isolation door assembly 400 can rotate synchronously, so that the first isolation door assembly 400 is capable of carrying and moving more wafer boats at the same time, thereby improving the work efficiency of the wafer processing device in processing wafers.

Referring to FIG. 11, the wafer boat loading and unloading region 200 includes at least one functional sub-region, the wafer loading and unloading region 300 includes at least one functional sub-region, and the number of functional sub-regions included in the wafer boat loading and unloading region 200 and the wafer loading and unloading region 300 may be the same or different. For example, some of the functional sub-regions of the wafer boat loading and unloading region 200 are configured for connecting the furnace tubes 100, and some of the functional sub-regions of the wafer boat loading and unloading region 200 are configured for pre-processing, cooling, or staging the wafer boat. Some of the functional sub-regions of the wafer loading and unloading region 300 are configured for wafer transferring into or removing from the wafer boat, and some of the functional sub-regions of the wafer loading and unloading region 300 are configured for pre-processing, cooling, or staging the wafer boat, which is determined based on specific situations. The first isolation door 410 and the wafer boat transfer mechanism rotate around the center of rotation, so that each isolation partition is sequentially connected to the functional sub-region, which in turn allows each wafer boat to transfer sequentially between different functional sub-regions. It can be understood that when the first isolation door 410 is rotated, the functional sub-regions are connected to each other, and after the rotation of the first isolation door 410 is completed and each isolation partition is connected to the functional sub-regions one by one, the first isolation door 410 is closed, so that an isolation is formed between the various functional sub-regions.

The number of functional sub-regions contained in the wafer boat loading and unloading region 200 and the wafer loading and unloading region 300 in the loading and unloading region may be provided according to actual needs. It is to be understood that the sum of the number of functional sub-regions contained in the wafer boat loading and unloading region 200 and the wafer loading and unloading region 300 is the same as the number of isolation partitions divided by the first isolation door 410, i.e., the multi-winged revolving door. In some embodiments, when the number of isolation partitions is an even number, the angle between the two main door wings connected in the first isolation door 410 is 180 degrees; when the number of isolation partitions is an odd number, the angle between the two main door wings connected in the first isolation door 410 is less than 180 degrees, but without limitation. The angle between the two main door wings connected in the first isolation door 410 may also be less than 180 degrees when the number of isolation partitions is an even number.

The wafer boat loading and unloading region 200 includes a plurality of functional sub-regions and/or the wafer loading and unloading region 300 includes a plurality of functional sub-regions, and a plurality of door wings 411 set in a circular array form a plurality of isolation sub-regions, and the wafer boat transfer mechanism is provided in the isolation sub-regions one-by-one correspondingly, so that each isolation sub-region is connected to the functional sub-regions in turn, such that each wafer boat is transferred in turn between different functional sub-regions, and more functional sub-regions are set for pre-processing, cooling, or temporary storage of the wafer boats, etc., which can further improve the efficiency of the wafer processing device in processing wafers, and since the first isolation door assembly 400 includes a first isolation door 410, i.e., a multi-winged revolving door, isolation between the multiple functional sub-regions is realized, further reducing contamination.

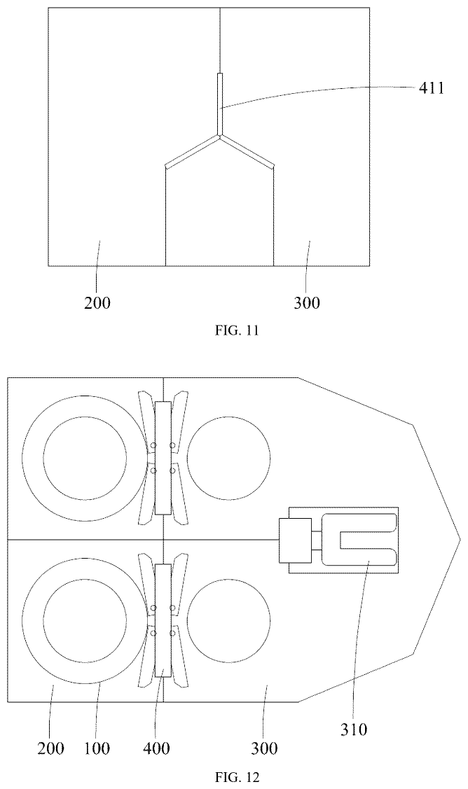

In some embodiments, see FIG. 12, the wafer processing device includes a plurality of loading and unloading regions and a plurality of furnace tubes 100, each loading and unloading region includes the wafer boat loading and unloading region 200 and the wafer loading and unloading region 300 connected via a communication region, and the first isolation door assemblies 400 are provided one-by-one for the communication region, and the wafer boat loading and unloading regions 200 are in communication one-by-one with the furnace tubes 100.

The wafer processing device includes a plurality of furnace tubes 100, and the plurality of furnace tubes 100 can simultaneously process the plurality of wafer boats, thereby improving the efficiency of the wafer processing device in processing wafers. The plurality of wafer loading and unloading regions 300 in the wafer processing device may share the wafer transfer machine, and accordingly may share the transfer region 500 and the transfer port 510, thereby reducing the cost of the wafer processing device and reducing the space occupied by the wafer processing device.

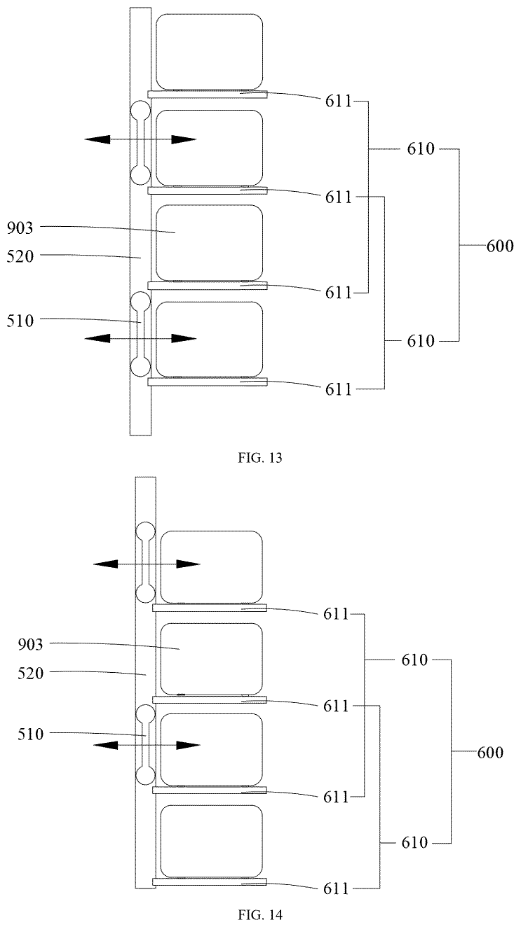

Referring to FIG. 2, FIG. 13 and FIG. 14 (FIG. 13 and FIG. 14 are A-A cross sections in FIG. 2), the wafer processing device further includes a transfer region 500 and a transfer port 510, the transfer port 510 is at least one, the transfer region 500 is provided on a side of the wafer loading and unloading region 300, and the transfer region 500 is configured for placing the wafer cassette 903. The transfer port 510 is provided on an isolation wall 520 between the wafer loading and unloading region 300 and the transfer region 500. The isolation wall 520 partially surrounds the wafer loader 310, the axial direction of the isolation wall 520 is parallel to the vertical direction, and the transfer port 510 is configured to at least allow wafers within the wafer cassette 903 to pass through. Preferably, the transfer port 510 is a front opening interface mechanical standard (FIMS) device, and the transfer port 510 is also configured to open or close the wafer cassette 903. The wafer loader 310 is configured to move wafers within the wafer cassette 903 into the wafer boat within the wafer loading and unloading region 300, and the wafer loader 310 is configured to move wafers from the wafer boat into the wafer cassette 903 in the transfer region 500.

A holder assembly 600 is provided on the side of the isolation wall 520 away from the wafer loader 310, the holder assembly 600 includes at least one wafer cassette holder 611, the wafer cassette holder 611 is configured to carry a portion of the wafer cassettes 903 in the transfer region 500. The holder assembly 600 includes n columns of the wafer cassette holders 611 provided circumferentially along the isolation wall 520, the at least one transfer port 510 is provided circumferentially along the isolation wall 520 into n columns, n is greater than or equal to 1, a column position of each column of the wafer cassette holders 611 is provided in correspondence with a column position of each column of transfer ports 510.

When n is equal to 1, a column of transfer ports 510 may include a plurality of transfer ports 510; when n is greater than 1, the plurality of columns of transfer ports 510 are provided around the wafer loader 310, such that the wafer loader 310 may access wafers in different wafer cassettes 903 through the plurality of transfer ports 510 as needed, or when wafers in the wafer cassette 903 are accessed completely, the wafer loader 310 can access wafers in another wafer cassette 903 in a timely manner, which improves the flexibility of operation of the internal structure of the wafer processing device and the work efficiency.

The holder assembly 600 is provided on the isolation wall 520, and the wafer cassette 903 is placed on the holder assembly 600, and the distance between the wafer cassette 903 and the wafer boat is shortened, which reduces time consuming of the wafer loading and unloading, and improves the efficiency of the wafer processing device.

In some embodiments, as shown in FIG. 2, the isolation wall 520 equidistantly partially surrounds the wafer loader 310, n is greater than or equal to 2. The isolation wall 520 equidistantly partially surrounding the wafer loader 310 may be such that at least a plurality of columns of transfer ports 510 on the isolation wall 520 equidistantly surround the wafer loader 310.

A plurality of columns of the wafer cassette holders 611 are provided along the circumferential direction of the isolation wall 520, the plurality of columns the transfer ports 510 are provided along the circumferential direction of the isolation wall 520, and the position of each column of the wafer cassette holders 611 is provided in correspondence with the position of each column of the transfer ports 510, the wafer loader 310 can load and unload wafers from the plurality of columns of the wafer cassette holders 611, and since the isolation wall 520 is configured to equidistantly partially surround the wafer loader 310, it is possible to cause the distance from the wafer loader 310 to each column of the wafer cassette holders 611 equal or approximately equal, which reduces the operational difficulty of wafer loading and unloading, improves the work efficiency of the wafer processing device, and simplifies the structural design of the wafer loader 310.

In some embodiments, among the n columns of the wafer cassette holders 611, the mth column of the wafer cassette holders 611 include a plurality of the wafer cassette holders 611 and the mth column of the wafer cassette holders 611 are divided into iₘ cassette holders 610, 1≤m≤n, iₘ is greater than or equal to 2. The wafer cassette holders 610 include jₘ wafer cassette holders 611, jₘ is greater than or equal to 1, and the iₘ wafer cassette holders 610 are distributed in the vertical direction. In the n columns of transfer ports 510, the mth column of transfer ports 510 include jₘ transfer ports 510, the mth column of transfer ports 510 correspond to the column positions of the mth column of the wafer cassette holders 611, and the jₘ transfer ports 510 in the mth column of transfer ports 510 have the same positional distribution as the jₘ wafer cassette holder 611 in any of the mth column of the wafer cassette holders 611. The mth column of the wafer cassette holders 611 are capable of moving in a vertical direction to align any of the jₘ wafer cassette holder units 610 in the mth column of the wafer cassette holders 611 with the mth column of transfer ports 510. As in the embodiments shown in FIGS. 2, 13, and 14, n=4, m=1, 2, 3, or 4, iₘ=2, and jₘ=2. It will be appreciated that for different columns of the n columns of cassette holders 611, i.e., when the value of m varies, the value of iₘ and the value of jₘ may vary with m, or for each column of the wafer cassette holders 611, the value of iₘ and the value of jₘ may not vary with m, as the case may be.

The mth column of the wafer cassette holders 611 include a plurality of the wafer cassette holders 611 and the mth column of the wafer cassette holders 611 are divided into iₘ wafer cassette holder units 610, and the cassette holders 611 may be provided above and below the mth column of the wafer cassette holders 611 included in the plurality of the wafer cassette holders 611, but it is to be understood that these other wafer cassette holders 611 do not belong to the mth column of the wafer cassette holders 611 included in the plurality of the wafer cassette holders 611.

The n columns of wafer cassette holders 611 are capable of moving in the vertical direction synchronously or asynchronously. The n columns of wafer cassette holders 611 moving synchronously in the vertical direction make the design of the holder assembly 600 simple; the n columns of wafer cassette holders 611 are capable of moving asynchronously in the vertical direction, which improves the working efficiency of wafer access.

As a result, the holder assembly 600 can be moved in the vertical direction to realize that the number of transfer ports 510 in the at least one column of transfer ports 510 is less than the number of the wafer cassette holders 611 in the corresponding column, and a plurality of the wafer cassette holders 611 in the corresponding column share the at least one column of transfer ports 510, which not only reduces the number of transfer ports 510 and reduces the production cost of the wafer processing device, but also leaves enough layout space for the transfer ports 510 and reduces the working efficiency of wafer access.

The jₘ is greater than or equal to 2, and the wafer cassette holders 611 in the mth column of the wafer cassette holders 611 in any two adjacent wafer cassette holder units 610 are provided alternately in the vertical direction. Exemplarily, as shown in FIGS. 13 and 14, each column of the wafer cassette holders 611 include four wafer cassette holders 611, the four wafer cassette holders 611 are divided into two wafer cassette holder units 610, the wafer cassette holder units 610 include two wafer cassette holders 611, and the wafer cassette holders 611 in any two adjacent wafer cassette holder units 610 are provided in the vertical direction alternatively. Each column of transfer ports 510 include two transfer ports 510.

When there is only a difference of one cassette holder 611 between two adjacent cassette holder units 610 provided alternatively in the vertical direction, when the holder assembly 600 is moved in the vertical direction, only the height of one cassette holder 611 is moved to realize that the wafer cassette holder 611 in the other adjacent wafer cassette holder unit 610 can be aligned with the transfer port 510, which reduces the vertical movement of the holder assembly 600 and reduces collision and contamination during movement. The travel of the holder assembly 600 in the vertical direction is reduced, which reduces collision and contamination during movement and improves the efficiency of wafer processing.

In other embodiments, when there is a difference of x wafer cassette holders 611 between two adjacent wafer cassette holder units 610 alternatively provided in the vertical direction, when the holder assembly 600 is moved in the vertical direction, only heights of x wafer cassette holders 611 are moved to realize the alignment of the wafer cassette holders 611 in the other adjacent wafer cassette holder units 610 with the transfer port 510, and obviously, X<jₘ.

Preferably, iₘ=2 and jₘ=2, that is, each column of the wafer cassette holders 611 include two wafer cassette holder units 610, and each wafer cassette holder unit 610 include two wafer cassette holders 611.

Each column of the wafer cassette holders 611 includes two wafer cassette holder units 610, and each wafer cassette holder unit 610 includes two wafer cassette holders 611, which can enable the wafer loader 310 to access wafers quickly, avoiding the speed of accessing wafers from becoming a bottleneck in improving the efficiency of the wafer processing device, and avoiding the wafer cassette holders 611 from being excessive, which can lead to an increase in the fabrication cost of the wafer processing device.

In some embodiments, the wafer processing device further includes a sealing device, and the sealing device may be provided in the wafer boat loading and unloading region 200 and on a side of the furnace tube 100. The sealing device may be configured to seal a connection end of the furnace tube 100 to the wafer boat loading and unloading region 200. The connection end of the furnace tube 100 and the wafer boat loading and unloading region 200 is sealed by the first wafer boat loader 210 when the furnace tube 100 processes the wafer boat, and the connection end of the furnace tube 100 and the wafer boat loading and unloading region 200 is sealed by the sealing device after the first wafer boat loader 210 is descended. Thus contaminants in the wafer boat loading and unloading region 200 are prevented from spreading into the furnace tube 100, avoiding contaminating the wafer subsequently processed by the furnace tube 100, and the number of cleaning and maintenance times of the furnace tube 100 is reduced.

The wafer processing device further includes an air blowing inlet and an exhaust outlet, the air blowing inlet is configured to vent inactive aires to blow the wafer boat loading region 200 and/or the wafer loading and unloading region 300, and the exhaust outlet is configured to exhaust the vented aires. In some embodiments, when the wafer boat loading and unloading region 200 is blown until the level of contamination meets the requirements, the isolation door device operates to allow the wafer boats to transfer between the wafer boat loading and unloading region 200 and the wafer loading and unloading region 300, which further reduces contamination caused by the reaction of by-products in the furnace tube 100. The furnace tube 100 and the wafer boat loading and unloading region 200 are provided in a vertical direction, the wafer boat loading and unloading region 200 and the wafer loading and unloading region 300 are provided in a first horizontal direction, and the air blowing inlet and the exhaust outlet may be provided in a second horizontal direction. Preferably, the first and second horizontal directions are perpendicular to each other to avoid that the air for blowing makes the air flow between the wafer boat loading and unloading region 200 and the wafer loading and unloading region 300 circulate, causing wafer contamination.

### Second Embodiment

The main difference between the first Embodiment and the second Embodiment is that the isolation door device is different.

In the first embodiment, the isolation door device is capable of driving the movement of the wafer boat, so that the wafer boat can transfer between the wafer loading and unloading region 200 and the wafer loading and unloading region 300 through the communication region. In the second embodiment, the isolation door device is capable of being started during the passage of the wafer boat and closing after the passage of the wafer boat. When the isolation door device is open, the wafer loading and unloading region 200 and the wafer loading and unloading region 300 are connected, and when the isolation door device is closed, the wafer loading and unloading region 200 and the wafer loading and unloading region 300 are separated by the isolation door device.

The isolation door device can be started when the wafer boat passes and be closed after the wafer boat passes, and the wafer boat can be moved without the aid of the isolation door device, thereby simplifying the structure of the isolation door device.

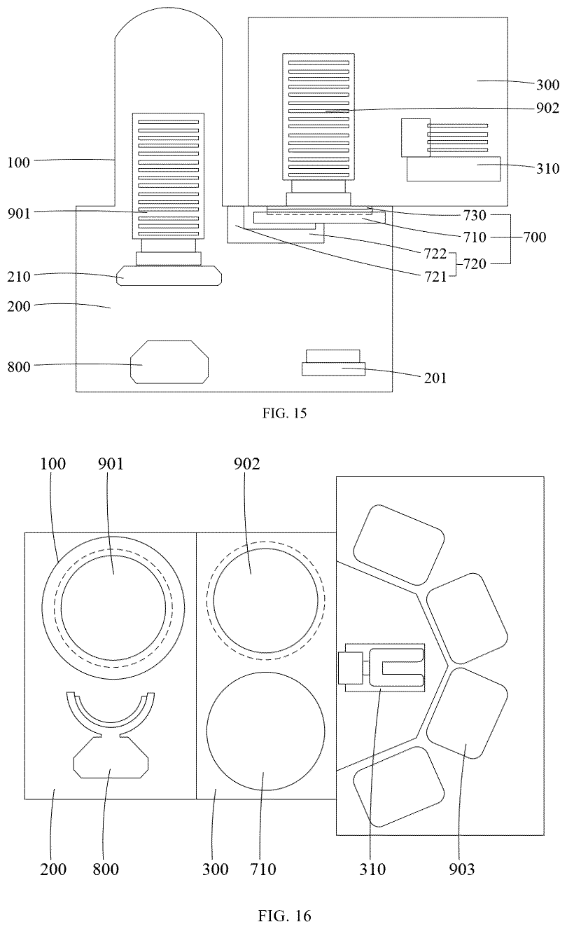

Referring to FIGS. 15 and 16, the isolation door device in this embodiment includes a second isolation door assembly 700. The second isolation door assembly 700 includes a second isolation door 710. The second isolation door assembly 700 includes a third state and a fourth state, the second isolation door 710 closes the communication region in the third state, and the second isolation door 710 opens the communication region in the fourth state. The second isolation door 710 may slide or rotate to open or close the communication region.

The second isolation door assembly 700 includes a second isolation door 710, and the second isolation door 710 is slidable or rotatable to open or close the communication region, to realize that the wafer boat loading and unloading region 200 and the wafer loading and unloading region 300 are connected or partitioned, the structure is simple.

In some embodiments, the furnace tube 100 and the wafer loading and unloading region 300 are provided on the same side of the wafer loading and unloading region 200. That is, the furnace tube 100 and the wafer boat loading and unloading region 200 are provided in a vertical direction, the furnace tube 100 and the wafer loading and unloading region 300 are both provided above the wafer boat loading and unloading region 200, and the furnace tube 100 and the wafer loading and unloading region 300 are provided in a horizontal direction. The second isolation door assembly 700 includes a fifth state, and in the fifth state, the second isolation door 710 closes the connection end of the furnace tube 100 to the wafer boat loading and unloading region 200.

The second isolation door 710 can be used both to isolate the wafer boat loading and unloading region 200 and the wafer loading and unloading region 300, and to close the connection end of the furnace tube 100 and the wafer boat loading and unloading region 200, i.e., the second isolation door 710 can be reused as a sealing device in the first embodiment, avoiding the contaminants in the wafer boat loading and unloading region 200 from spreading to the furnace tube 100 to avoid contaminating wafers to be subsequently processed by the furnace tube 100, and the number of the furnace tube 100 being cleaned and maintained is reduced, the structure of the wafer processing device is simplified.

Exemplarily, the second isolation door assembly 700 includes a second isolation door 710 and a door drive mechanism 720, the door drive mechanism 720 includes a door shaft 721 and a cross beam 722, the door shaft 721 is rotatably provided between the furnace tube 100 and the wafer loading and unloading region 300, and the cross beam 722 connects the second isolation door 710 to the door shaft 721. The second isolation door 710 rotates around the door shaft 721, and closes a lower end (i.e., the connection end of the furnace tube 100 to the wafer loading and unloading region 200, i.e., the fifth state) of the furnace tube 100 or the communication region (i.e., the third state), or located between the lower end of the furnace tube 100 and the communication region (i.e., the fourth state). Referring to FIG. 16, the second isolation door 710 may be located in the position shown, i.e., the second isolation door assembly 700 shown in FIG. 16 is in the fourth state. The second isolation door 710 may also be located in the position shown by the dashed line in FIG. 16, the second isolation door assembly 700 is located in the fifth state when the second isolation door 710 is located in the position shown by the dashed line on the left, and the second isolation door assembly 700 is in a third state when the second isolation door 710 is located in the position shown by the dotted line on the right.

The second isolation door 710 may be provided in one of the three positions of the lower end of the furnace tube 100, the communication region, or between the lower end of the furnace tube 100 and the communication region. The second isolation door 710 is driven to rotate by the door drive mechanism 720, so that the second isolation door 710 moves among the three positions of the lower end of the furnace tube 100, the communication region, or between the lower end of the furnace tube 100 and the communication region, in order to realize position switching, and the structure of the second isolation door assembly 700 is simpler.

In some embodiments, the second isolation door assembly 700 includes a second wafer boat loader 730, the second wafer boat loader 730 is provided at the wafer loading and unloading region 200. The second wafer boat loader 730 is configured to move the wafer boat into the wafer loading and unloading region 300 and close the communication region, and the second wafer boat loader 730 is configured to move the wafer boat out of the wafer loading and unloading region 300.

The second isolation door assembly 700 includes a second wafer boat loader 730, and the second wafer boat loader 730 is configured to both move the wafer boat into or out of the wafer loading and unloading region 300 and to isolate the communication region between the wafer loading and unloading region 200 and the wafer loading and unloading region 300, and multiplexing the second wafer boat loader 730 can simplify the structure of the wafer processing device.

In some embodiments, the furnace tube 100 and the wafer boat loading and unloading region 200 are provided in the vertical direction, and the furnace tube 100 and the wafer loading and unloading region 300 are provided on the same side of the wafer boat loading and unloading region 200. When loading and unloading the wafer boat, the first wafer boat loader 210 and the second wafer boat loader 730 drive the wafer boat to move in the vertical direction.

The furnace tube 100 and the wafer boat loading and unloading region 200 are provided in the vertical direction, that is, the wafer processing device includes a vertical furnace, and the furnace tube 100 and the wafer loading and unloading region 300 are provided on the same side of the wafer boat loading and unloading region 200, and when loading and unloading the wafer boat, the first wafer boat loader 210 and the second wafer boat loader 730 drive the wafer boat to move in the vertical direction, and the first wafer boat loader 210 and the second wafer boat loader 730 have the same structure, which is conducive to reducing wafer processing. The first wafer boat loader 210 and the second wafer boat loader 730 have the same structure, which is conducive to reducing the production cost of the wafer processing device.

Preferably, the second isolation door assembly 700 includes a second isolation door 710 and a second wafer boat loader 730. When the wafer processing device works, the first wafer boat 901 is processed in the furnace tube 100, the first wafer boat loader 210 seals the lower end of the furnace tube 100 during processing, the second wafer boat 902 loads the wafer in the wafer loading and unloading region 300, and at this time, the second wafer boat loader 730 can separate the wafer boat loading and unloading region 200 and wafer loading and unloading region 300. When the first wafer boat 901 is processed completely, the first wafer boat loader 210 descends, and the first wafer boat 901 carried by the first wafer boat loader 210 may be transferred by the wafer boat transferring device 800 to a temporary storage position 201 in the wafer boat loading and unloading region 200, and the temporary storage position 201 may be configured to temporarily store the wafer boat, so that the wafer boat waits for a next step in the position to be processed, to be pretreatment or cooling, and the second isolation door 710 may be rotated to the lower end of the furnace tube 100 to close the furnace tube 100. The second wafer boat 902 in the wafer loading and unloading region 300 that completes wafer loading is moved to the wafer loading and unloading region 200 by the second wafer boat loader 730, and the wafer boat transfer device 800 transfers the second wafer boat 902 to a first wafer boat loader 210, and the first wafer boat loader 210 moves the second wafer boat 902 into the furnace tube 100 for processing, and after the second wafer boat 902 is descended, the second isolation door 710 can be rotated to the communication region to isolate the wafer loading and unloading region 200 and the wafer loading and unloading region 300. After the first wafer boat 901 is cooled down, the wafer boat transfer device 800 transfers the first wafer boat 901 to the second wafer boat loader 730, and the second isolation door 710 is rotated to the position between the lower end of the furnace tube 100 and the communication region, the second wafer boat loader 730 transfers the first wafer boat 901 to the wafer loading and unloading region 300 and isolates the wafer loading and unloading region 200 from the wafer loading and unloading region 300.

The second isolation door assembly 700 includes the second isolation door 710 and the second wafer boat loader 730, which can quickly complete the exchange of the location of the two wafer boats, thereby reducing the time for connecting the wafer boat loading and unloading region 200 and the wafer loading and unloading region 300, and helping to reduce the risk of the by-products contaminating the wafer boats and the wafer on the wafer boats.

It should be noted that the main difference between the second embodiment and the first embodiment is that the isolation door device is different. Structures other than the isolation door device in first embodiment, including the setting of the transfer port 510, the holder assembly 600, and the transfer region 500, are also applicable to the second embodiment, and therefore will not be repeated in the second embodiment.

The terms “first”, “second”, and the like are used for descriptive purposes only, and are not to be understood as indicating or implying relative importance or implicitly specifying the number of technical features indicated. Thus, a feature defined with “first”, “second”, etc. may include one or more such features, either explicitly or implicitly. In the description of the present application, “more than one” means two or more, unless otherwise expressly and specifically limited.

In this application, unless otherwise expressly specified and limited, the terms “assembly”, “connection” and the like are to be broadly construed, e.g., as a fixed connection, a detachable connection, a one-piece connection, a mechanical connection, or an electrical connection; It may be a direct connection or an indirect connection through an intermediate medium, a connection within two elements or an interactive relationship between two elements. For those of ordinary skill in the art, the specific meanings of the above terms in this application may be understood on a case-by-case basis.

In the description of the present specification, the description with reference to the terms “some embodiments”, “exemplarily”, and the like means that specific features, structures, materials, or characteristics described in conjunction with the embodiments or examples are included in at least one embodiment or example of the present application. In this specification, schematic expressions of the above terms need not be directed to the same embodiment or example. Moreover, the specific features, structures, materials, or characteristics described may be combined in any one or more embodiments or examples in a suitable manner. Moreover, without contradicting each other, those skilled in the art may combine and combine different embodiments or examples and features of different embodiments or examples described in this specification.

Although the embodiments of the present application have been shown and described above, it is understood that the above embodiments are exemplary and cannot be construed as a limitation of the present application, and that those skilled in the art may make changes, modifications, substitutions, and variations of the above embodiments within the scope of the present application, and therefore, any changes or modifications made in accordance with the claims and the specification of the present application shall fall within the scope of the patent coverage of the present application.

What is claimed is:

1. A wafer processing device, comprising:
a furnace tube;
a loading and unloading region, comprising a wafer boat loading and unloading region and a wafer loading and unloading region connected via a communication region, wherein the wafer boat loading and unloading region is in communication with the furnace tube, the wafer boat loading and unloading region comprises a first wafer boat loader for at least moving a wafer boat into or out of the furnace tube, and the wafer loading and unloading region comprises a wafer loader for at least moving a wafer into or out of the wafer boat; and
an isolation door device, provided in the communication region, wherein the isolation door device is capable of isolating the wafer boat loading and unloading region from the wafer loading and unloading region, and operating to enable a transferring of the wafer between the wafer boat loading and unloading region and the wafer loading and unloading region through the communication region.

2. The wafer processing device according to claim 1, wherein the isolation door device is capable of driving a movement of the wafer boat to transfer between the wafer boat loading and unloading region and the wafer loading and unloading region through the communication region.

3. The wafer processing device according to claim 2, wherein the isolation door device comprises a first isolation door assembly, and the first isolation door assembly comprises a first isolation door and a plurality of wafer boat transfer mechanisms, each wafer boat transfer mechanism is configured to carry and move at least one wafer boat;
the plurality of wafer boat transfer mechanisms comprise a first wafer boat transfer mechanism and a second wafer boat transfer mechanism, the first wafer boat transfer mechanism and the second wafer boat transfer mechanism are provided on a first side and a second side of the first isolation door opposite to each other;
at least the plurality of wafer boat transfer mechanisms are capable of rotating around a center of rotation to form a first state and a second state;
in the first state, the first wafer boat transfer mechanism is provided in the wafer boat loading and unloading region, and the second wafer boat transfer mechanism is provided in the wafer loading and unloading region; and
in the second state, the second wafer boat transfer mechanism is provided in the wafer loading and unloading region and the first wafer boat transfer mechanism is located in the wafer loading and unloading region.

4. The wafer processing device according to claim 3, wherein each wafer boat transfer mechanism comprises a support seat, the support seat is configured to carry the wafer boat and move the carried wafer boat when rotating around the center of rotation;
the support seat of the first wafer boat transfer mechanism and the support seat of the second wafer boat transfer mechanism are connected by a connection member, and the connection member is connected to the first isolation door;
the connection member and the support seat are provided on a same side of the first isolation door;
the support seat, the connection member and the first isolation door are capable of synchronously rotating about the center of rotation to switch the plurality of wafer boat transfer mechanisms between the first state and the second state; and/or
each wafer boat transfer mechanism comprises a wafer boat holder and a holder rotation shaft, wherein the wafer boat holder is provided on the holder rotation shaft, the holder rotation shaft is connected to the first isolation door, and the wafer boat holder is capable of rotating about the holder rotation shaft to hold the wafer boat to carry the wafer boat;
wherein the wafer boat holder is capable of rotating about the holder rotation shaft to release the held wafer boat, and the wafer boat holder, the holder rotation shaft and the first isolation door are capable of synchronously rotating about the center of rotation to move the held wafer boat and of switching the plurality of wafer boat transfer mechanisms between the first state and the second state.

5. The wafer processing device according to claim 4, wherein the wafer boat holder comprises a plurality of wafer boat sub-holders, the holder rotation shaft comprises a plurality of holder sub-rotation shafts, the plurality of wafer boat sub-holders are provided on the plurality of holder sub-rotation shafts, the plurality of holder sub-rotation shafts are connected to the first isolation door, and the plurality of holder sub-rotation shafts are capable of rotating around the plurality of holder sub-rotation shafts;
wherein the wafer boat holder being capable of rotating about the holder rotation shaft to hold the wafer boat to carry the wafer boat comprises the plurality of wafer boat sub-holders of the wafer boat holder being capable of rotating to gather and clamp the wafer boat to carry the wafer boat; and
wherein the wafer boat holder being capable of rotating about the holder rotation shaft to release the held wafer boat comprises the plurality of wafer boat sub-holders of the wafer boat holder being capable of rotating to separate to release the clamped wafer boat.

6. The wafer processing device according to claim 4, wherein each wafer boat transfer mechanism comprises the wafer boat holder and the holder rotation shaft, and each wafer boat transfer mechanism is configured to:
before the wafer boat holder, the holder rotation shaft, and the first isolation door rotate about the center of rotation to move the held wafer boat, the wafer boat holder is capable of rotating about the holder rotation shaft to hold the wafer boat to carry the wafer boat, and the wafer boat holder is capable of rising to lift the held wafer boat; and
after the wafer boat holder, the holder rotation shaft and the first isolation door rotate about the center of rotation to move the held wafer boat, the wafer boat holder is capable of descending to lower the held wafer boat, and the wafer boat holder is capable of rotating about the holder rotation shaft to release the held wafer boat.

7. The wafer processing device according to claim 3, wherein the first isolation door and each wafer boat transfer mechanism are capable of rotating synchronously, the first isolation door assembly further comprises a sealing member, a gap is formed between the sealing member and the first isolation door when the first isolation door and each wafer boat transfer mechanism rotate, and when the first isolation door and each wafer boat transfer mechanism stop rotating, the sealing member seals the gap between the loading and unloading region and the first isolation door.

8. The wafer processing device according to claim 7, wherein the first isolation door is a multi-winged revolving door, the multi-winged revolving door comprises at least three door wings, and the at least three door wings comprise two main door wings and at least one sub-wing, wherein the two main door wings are connected to divide the first side and the second side of the first isolation door, and the at least one sub-wing is provided on the first side of the first isolation door and/or the second side of the first isolation door;
angles between adjacent door wings are equal, wherein each wafer boat transfer mechanism is provided one-to-one between the adjacent door wings, and each wafer boat transfer mechanism and the multi-winged revolving door are capable of rotating about the center of rotation to drive the wafer boat to transfer between the wafer boat loading and unloading region and the wafer loading and unloading region through the communication region.

9. The wafer processing device according to claim 8, wherein the wafer boat loading and unloading region comprises a plurality of functional sub-regions and/or the wafer loading and unloading region comprises a plurality of functional sub-regions, and an isolation partition is formed between the adjacent door wings, and the multi-winged revolving door and each wafer boat transfer mechanism rotate about the center of rotation, to make each isolation partition to be in communication with the plurality of functional sub-regions in turn.

10. The wafer processing device according to claim 1, wherein the wafer processing device comprises a plurality of wafer boat loading and unloading regions and a plurality of furnace tubes, the plurality of wafer boat loading and unloading regions are one-to-one correspondingly in communication with the plurality of furnace tubes.

11. The wafer processing device according to claim 1, wherein the isolation door device is capable of being started when the wafer boat passes through and closing after the wafer boat passes through.

12. The wafer processing device according to claim 11, wherein the isolation door device comprises a second isolation door assembly;
the second isolation door assembly comprises a second isolation door, and the second isolation door assembly comprises a third state and a fourth state;
wherein in the third state, the second isolation door closes the communication region, and
in the fourth state, the second isolation door opens the communication region; and/or
wherein the second isolation door assembly comprises a second wafer boat loader, the second wafer boat loader is provided in the wafer loading and unloading region, the second wafer boat loader is configured to move the wafer boat into the wafer loading and unloading region and to close the communication region, and the second wafer boat loader is configured to move the wafer boat out of the wafer loading and unloading region.

13. The wafer processing device according to claim 12, wherein the second isolation door assembly comprises the second isolation door, the furnace tube and the wafer loading and unloading region are provided on a same side of the wafer loading and unloading region, and the second isolation door assembly comprises a fifth state in which the second isolation door closes a connection end of the furnace tube to the wafer loading and unloading region.

14. The wafer processing device according to claim 12, wherein the second isolation door assembly comprises the second isolation door and a door actuation mechanism, the door actuation mechanism comprises a door shaft and a cross beam, the door shaft is rotatably provided between the furnace tube and the wafer loading and unloading region, and the cross beam connects the second isolation door and the door shaft.

15. The wafer processing device according to claim 12, wherein the furnace tube and the wafer boat loading and unloading region are provided in a vertical direction, the furnace tube and the wafer loading and unloading region are provided on a same side of the wafer boat loading and unloading region, and when loading and unloading the wafer boat, the first wafer boat loader and the second wafer boat loader drives the wafer boat to move in the vertical direction.

16. The wafer processing device according to claim 1, further comprising a transfer region and at least one transfer port;
the transfer region is provided on a side of the wafer loading and unloading region, the transfer region is configured for placing a wafer cassette, the at least one transfer port is provided on an isolation wall between the wafer loading and unloading region and the transfer region;
the isolation wall partially surrounds the wafer loader, an axial direction of the isolation wall is parallel to a vertical direction, the at least one transfer port is configured for the wafer at least inside the wafer cassette passing through;
the wafer loader is configured to move the wafer inside the wafer cassette into the wafer boat in the wafer loading and unloading region, and the wafer loader is configured to move the wafer from the wafer boat into the wafer cassette in the transfer region;
a side of the isolation wall away from the wafer loader is provided with a holder assembly, the holder assembly comprises at least one wafer cassette holder, the at least one wafer cassette holder is configured to carry the wafer cassette in the transfer region; and
the holder assembly comprises n columns of wafer cassette holders provided circumferentially along the isolation wall, the at least one transfer port is provided in n columns, n≥1, along a circumference of the isolation wall, a column position of each column of the wafer cassette holders is provided in correspondence with a column position of each column of the at least one transfer port.

17. The wafer processing device according to claim 16, wherein the isolation wall equidistantly partially surrounds the wafer loader, n≥2.

18. The wafer processing device according to claim 16, wherein in the n columns of wafer cassette holders, a mth column of wafer cassette holders comprise a plurality of the wafer cassette holders and the mth column of the wafer cassette holders are divided into iₘ cassette holder units, 1≤m≤n, iₘ≥2, and each wafer cassette holder unit comprises jₘ wafer cassette holders, jₘ≥1, and iₘ cassette holder units are distributed along the vertical direction;
in the n columns of transfer ports, a mth column of the transfer ports comprise jₘ transfer ports, the mth column of transfer ports correspond to column positions of the mth column of the wafer cassette holders, the jₘ transfer ports in the mth column of transfer ports have a same positional distribution as the jₘ wafer cassette holders in any wafer cassette holder unit of the mth column of the wafer cassette holders; and
the mth column of wafer cassette holders are capable of moving in the vertical direction to align any of the wafer cassette holder units of the mth column of wafer cassette holders with the mth column of transfer ports.

19. The wafer processing device according to claim 18, wherein jₘ≥2, the wafer cassette holders in any two adjacent wafer cassette holder units of the mth column of the wafer cassette holders are alternatively provided in the vertical direction.
